(19) United States
(12) Patent Application Publication
(10) Pub. No.: US 2026/0060131 A1
(43) Pub. Date: Feb. 26, 2026

(54) ELECTRONIC DEVICE HAVING AN IMPROVED MOLD-FLOW DESIGN

(71) Applicant: TEXAS INSTRUMENTS INCORPORATED, DALLAS, TX (US)

(72) Inventors: CHU-YUN LO, Taipei City (TW); CHIA WEI CHANG, TAOYUAN CITY (TW); HANK SUNG, Sachse, TX (US)

(21) Appl. No.: 18/813,885

(22) Filed: Aug. 23, 2024

(51) Int. Cl. H01L 23/31; H01L 21/48; H01L 21/56; H01L 23/00; H01L 23/367; H01L 23/495

(52) U.S. Cl. CPC H01L 23/3107; H01L 21/4825; H01L 21/4882; H01L 21/565; H01L 23/367; H01L 23/49541; H01L 24/32; H01L 24/48; H01L 2224/32221; H01L 2224/48175; H01L 2924/141

(57) ABSTRACT

An electronic device includes a leadframe where the leadframe includes a first set of leads, a second set of leads, and conductive pads. A heat sink is attached to the conductive pads. The heat sink includes a pair of heat sink pads separated by a gap, and a die attach pad. The die attach pad has a semi-circular shape and is connected to an end of each of the pair of heat sink pads to form a U-shape. The die attach pad further includes an airgap prevention feature. A die is attached to the heat sink and wire bonds connect the die to the leadframe. A mold compound encapsulates the heat sink, the die, and the wire bonds.

### TECHNICAL FIELD

The present disclosure relates to electronic devices, and more specifically to electronic device having an improved mold-flow design to mitigate voids in the mold compound.

### BACKGROUND

Partial discharge in a high-voltage electronic device (e.g., integrated circuit) compromises the performance and longevity of the electronic device. Partial discharge occurs due to voids or airgaps in an insulting material (e.g., mold compound). Partial discharge causes electrical leaking inside the electronic device which compromises performance of the electronic device. In addition, partial discharge will cause progressive deterioration of the mold compound ultimately leading to electrical breakdown thereby decreasing the life of the electronic device.

### SUMMARY

In a described example, an electronic device includes a leadframe where the leadframe includes a first set of leads, a second set of leads, and conductive pads. A heat sink is attached to the conductive pads and includes an airgap prevention feature. A die is attached to the heat sink and wire bonds are connected from the die to the leadframe. A mold compound encapsulates the heat sink, the die, and the wire bonds.

In another described example, an electronic device includes a leadframe, the leadframe includes a first set of leads, a second set of leads, and conductive pads. A heat sink is attached to the conductive pads. The heat sink includes a pair of heat sink pads separated by a gap, and a die attach pad. The die attach pad has a semi-circular shape and is connected to an end of each of the pair of heat sink pads to form a U-shape. The die attach pad further includes an airgap prevention feature. A die is attached to the heat sink and wire bonds connect the die to the leadframe. A mold compound encapsulates the heat sink, the die, and the wire bonds.

In still another described example, a method includes attaching a heat sink to a leadframe, where the heat sink includes conductive pads and a die attach pad. The die attach pad has a semi-circular gap formed therein that includes a beveled inner wall that extends from a first surface of the die attach pad to a second surface of the die attach pad. A die is attached to the die attach pad and wire bonds are attached from the die to the leadframe. A mold compound is formed over the heat sink, the die, and the wire bonds.

### BRIEF DESCRIPTION OF THE DRAWINGS

FIGS. 1A and 1B are top perspective and bottom views respectively of an example electronic device.

FIG. 1C is a close-up bottom view of a die attach pad of a heat sink of the electronic device of FIGS. 1A and 1B.

FIGS. 1D-1F are cross-sectional views of the die attach pad of FIG. 1C illustrating the formation of a mold compound around the die attach pad.

FIG. 2A is a close-up bottom view of another die attach pad of another heat sink of another example electronic device.

FIGS. 2B and 2C are cross-sectional views of the die attach pad of FIG. 2A illustrating the formation of a mold compound around the die attach pad.

FIG. 3 is a block diagram flow chart explaining a fabrication process of the electronic device of FIGS. 1A and 1B.

FIG. 4A illustrates a cross-sectional view of a leadframe in the early stages of fabrication.

FIG. 4B illustrates a cross-sectional view of the leadframe of FIG. 4A after attaching a heat sink to the leadframe.

FIG. 4C illustrates a cross-sectional view of the leadframe of FIG. 4B after attaching an insulating tape to the heat sink.

FIG. 4D illustrates a cross-sectional view of the leadframe of FIG. 4C after placing a die on the insulating tape.

FIG. 4E illustrates a cross-sectional view of the leadframe of FIG. 4D after attachment of wire bonds from the die to the leadframe.

FIG. 4F illustrates a cross-sectional view of the leadframe of FIG. 4E after undergoing formation of a mold compound.

### DETAILED DESCRIPTION

In certain electronic devices (e.g., integrated circuit (IC) packages) during formation of a mold compound, voids or airgaps can become present in the mold compound due to the configuration of components in the electronic device. In other words, as the mold compound is forming around the components of the electronic device, one or more components may be configured such that a void or airgap can occur between the component and the mold compound. Since the electronic devices are high-voltage devices, the voids can cause a partial discharge within the mold compound of the electronic device. Partial discharge causes electrical leaking inside the electronic device which compromises performance of the electronic device. In addition, partial discharge will cause progressive deterioration of the mold compound ultimately leading to electrical breakdown thereby decreasing the life of the electronic device.

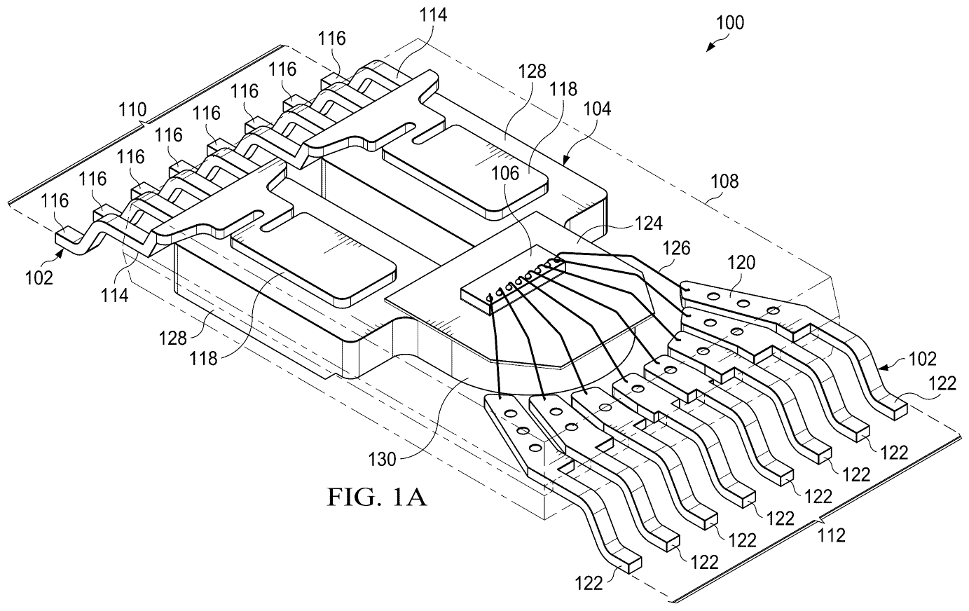

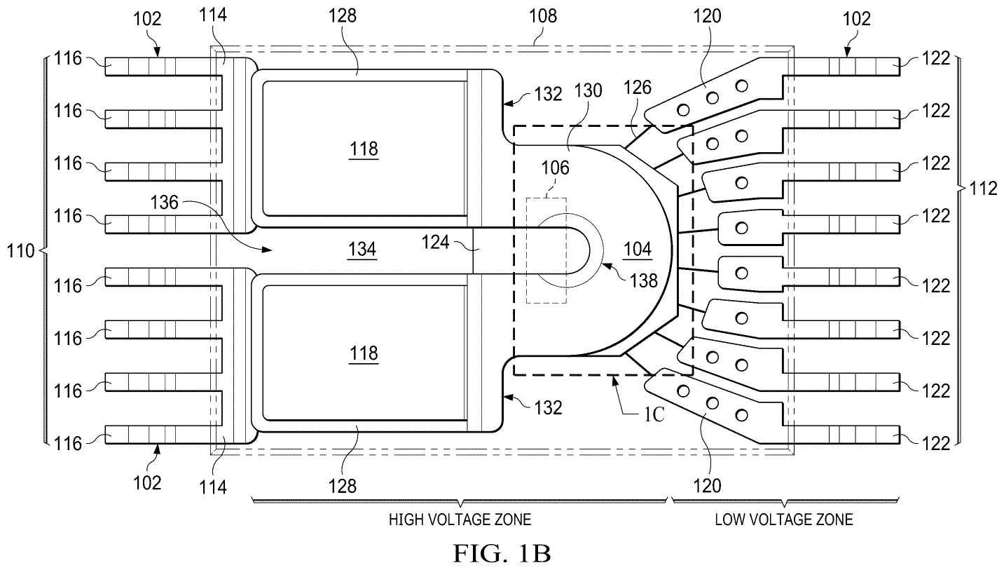

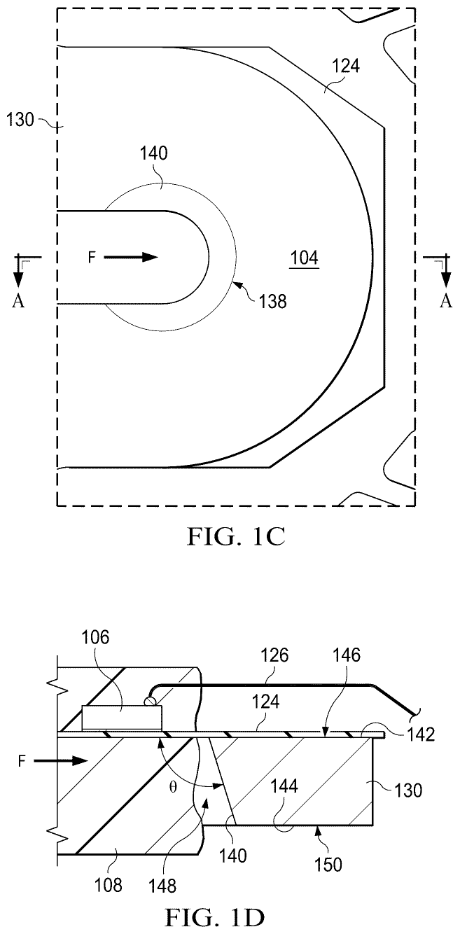

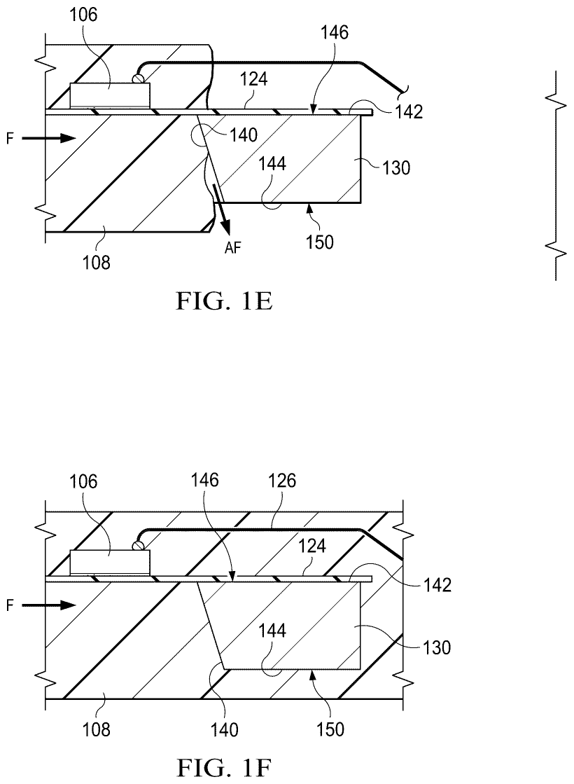

Referring to FIGS. 1A and 1B, disclosed herein is an example electronic device (e.g., integrated circuit (IC) package) 100 having an improved mold-flow configuration to prevent formation of voids in a mold compound thereby overcoming the aforementioned disadvantages. The example electronic device 100 disclosed herein can be any type of device, such as a small outline IC (SOIC) package where voids can occur at an interface between the mold compound and a component in the electronic device 100 during formation of the mold compound. For explanation purposes only, the example electronic device 100 disclosed herein is an example current detection device that may for example include a Hall-effect current sensor. Thus, the example current detection device is for illustrative purposes only and is not intended to limit the scope of the invention.

The electronic device 100 includes a leadframe 102, a heat sink 104, a sensor die 106, and mold compound 108. The leadframe 102 is comprised of a first set of leads 110 and a second set of leads 112. The first set of leads 110 includes first inner leads 114, first external leads 116, and conductive pads (e.g., current detection pads) 118 connected to the first inner leads 114. The second set of leads 112 includes second inner leads 120 and second external leads 122. The die 106 is attached to the heat sink 104 and an insulating tape (e.g., Pi tape) 124 is disposed between the die 106 and the heat sink 104. Wire bonds 126 provide a connection from the die 106 to the second inner leads 120. The mold compound 108 is formed over the heat sink 104, the die 106, the first and second inner leads 114, 120, the pads 118, and the wire bonds 126. A bottom surface of the pads 118 are exposed as illustrated in FIG. 1B.

The heat sink 104 has a U-shaped configuration and comprises a pair of heat sink pads 128 and a die attach pad 130. The conductive pads 118 from the leadframe 102 are attached to the pair of heat sink pads 128. The die attach pad 130 has a semi-circular shape and connects to an end 132 of each of the pair of heat sink pads 128 to form the U-shape. Thus, a gap 134 separates the pair of heat sink pads 128 from each other. The gap has an open end 136 and a closed end 138. The gap 134 extends into and terminates at the closed end 138 in the die attach pad 130.

Referring also to FIG. 1C, FIG. 1C is a close-up bottom view of the die attach pad 130 as illustrated by the outlined box in FIG. 1B. For simplicity and clarity, the die 106 has been removed from FIG. 1C. The closed end 138 of the gap 134 has a semi-circular shape and an airgap prevention feature comprising a beveled inner side wall 140 to form a cone shape. The beveled side wall 140 facilitates the flow of the mold compound 108 during fabrication of the electronic device 100 to prevent voids or airgaps from forming at an interface between the mold compound 108 and the beveled side wall 140. The direction D of the flow of the mold compound 108 is represented by the arrow F in FIGS. 1C-1F.

Specifically, FIGS. 1D-1F illustrate how the mold compound 108 is formed around the die attach pad 130 of the heat sink 104. FIGS. 1D-1F are 180° flipped cross-sectional views of the die attach pad 130 taken along the line A-A of FIG. 1C. The beveled side wall 140 extends from a first (top) surface 142 and slopes at an angle θ in a range of approximately 95° to 145° with respect to the first surface 142 to a second (opposite bottom) surface 144 of the die attach pad 130. As illustrated in the figures, the slope of the beveled side wall 140 forces air to flow downward as indicated by the arrow AF in FIG. 1E. If the slope angle θ is less than 95° airgaps can form in the mold compound 108 since the slope is too small to force the air downward. If the slope angle θ is greater than 145° then the amount of material (e.g., copper) removed from the die attach pad 130 of the heat sink 104 to form the larger angle would be too large resulting in a small die attach pad 130 cross section. As result, the electronic device 100 would not meet product specifications (e.g., current rating, voltage rating, etc.).

Specifically, referring to FIG. 1D, during formation of the mold compound 108, the mold compound 108 flows along each side of the insulating tape 124 toward the die attach pad 130. The mold compound 108 approaches and contacts an upper portion 146 of the die attach pad 130 first thereby creating an airgap 148 between the mold compound 108 and the beveled side wall 140 of the die attach pad 130. As the mold compound 108 progresses, the mold compound 108 contacts more of the beveled or sloped side wall 140 and is forced downward toward a lower portion 150 of the die attach pad 130. This progression reduces the size of the airgap 148 and forces air to flow outward from the interface between the mold compound 108 and the beveled side wall 140 of the die attach pad 130, as indicated by the arrow AF in FIG. 1E. As the mold compound 108 progresses, eventually all the air is removed from the airgap 148 and the mold compound 108 encapsulates the die attach pad 130 without the formation of any voids or gaps in the mold compound 108 as illustrated in FIG. 1F.

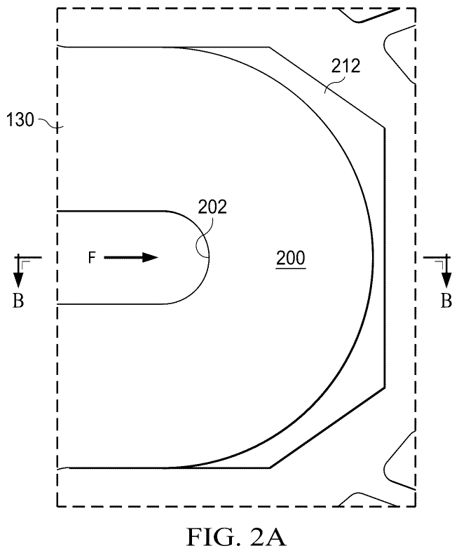

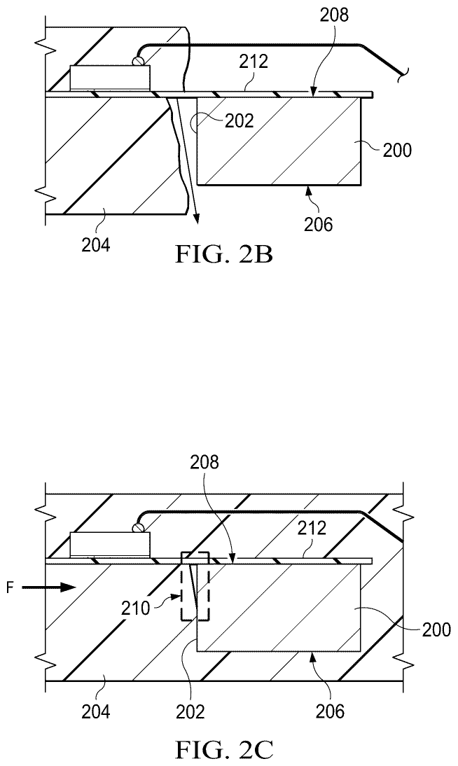

FIG. 2A is a close-up bottom view of another example die attach pad 200 from a similar electronic device as described above. FIGS. 2B and 2C are flipped cross-sectional views of the die attach pad 200 of FIG. 2A taken along lie B-B. The die attach pad 200 illustrated in FIG. 2A, however, does not include a beveled inner side wall at the closed end of the gap as the electronic device 100 described above. Rather, the die attach pad 200 includes a straight inner side wall 202 as illustrated in FIGS. 2B and 2C. Thus, as the mold compound 204 progresses toward the straight side wall 202 as indicated by the arrow F, the mold compound 204 contacts a bottom portion 206 of the straight inner side wall 202 before it contacts an upper portion 208. This is due to a flow speed difference between upper and lower portions of the mold compound 204. In other words, the lower portions of the mold compound 204 moves more rapidly than the upper portion. As a result, a void or airgap 210 is formed at an interface between the mold compound 204, the die attach pad 200, and the insulating tape 212.

On the other hand, as illustrated in FIGS. 1D-1F and as described above, the beveled inner wall 140 of the electronic device 100 compensates for this difference in flow speed between the upper and lower portions of the mold compound 108. As a result, the beveled inner wall 140 prevents any formation of voids or airgaps during formation of the mold compound 108.

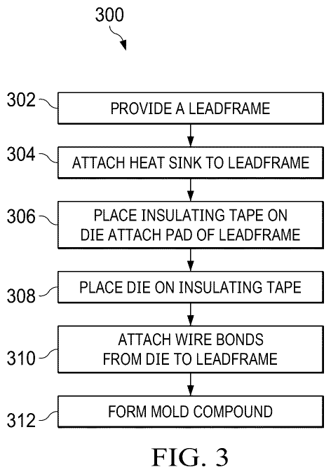

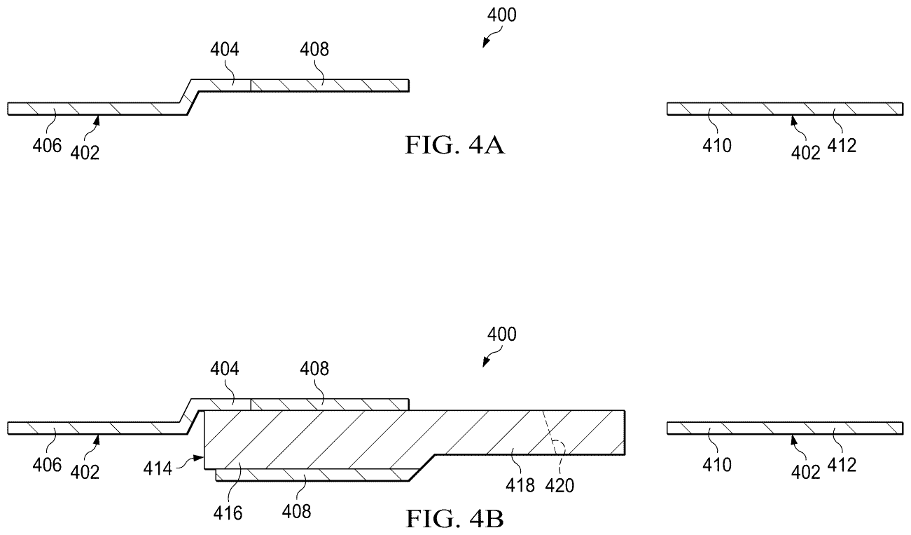

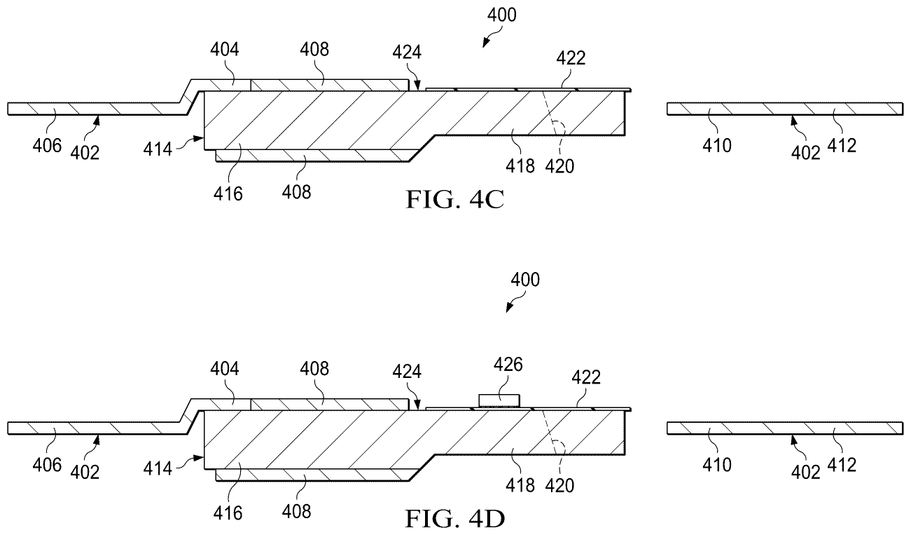

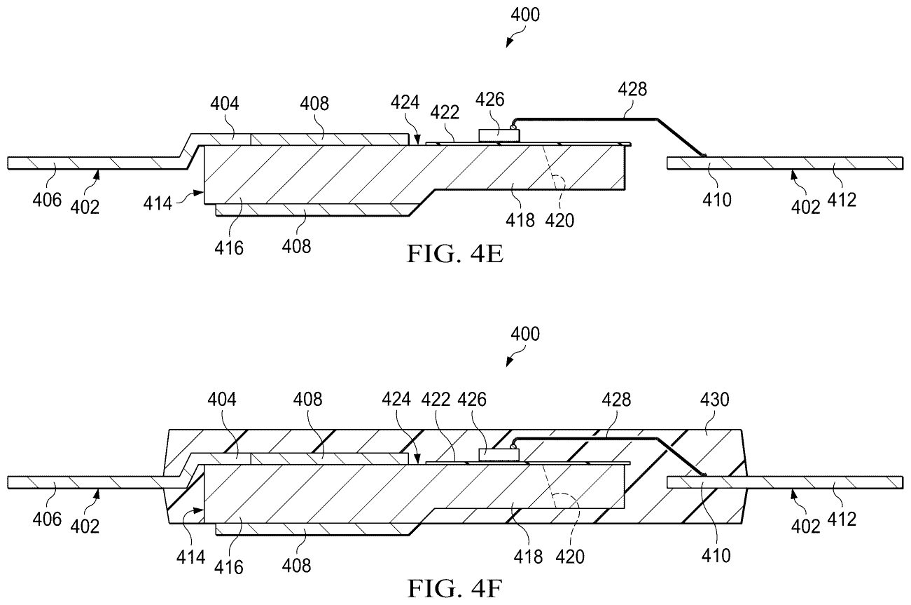

FIG. 3 is a block diagram flow chart explaining a fabrication process 300 and FIGS. 4A-4F illustrate a fabrication process 400 associated with the formation of the electronic device 100 illustrated in FIGS. 1A and 1B. Though depicted sequentially as a matter of convenience, at least some of the actions shown can be performed in a different order and/or performed in parallel. Alternatively, some implementations may perform only some of the actions shown. Still further, although the example illustrated in FIGS. 3 and 4A-4F is an example method illustrating the example configuration of FIGS. 1A and 1B, other methods and configurations are possible. It is understood that although the method illustrated in FIGS. 3 and 4A-4F depicts the fabrication process of a single electronic device, the process applies to an array of electronic devices. Thus, after fabrication of the array of electronic devices the array is singulated to separate each electronic device 100 from the array.

Referring to FIG. 3 and to FIGS. 4A-4F, the fabrication process 400 of the electronic device 100 illustrated in FIGS. 1A and 1B begins at 302 where a leadframe 402 is provided as illustrated in FIG. 4A. The leadframe 402 includes first inner leads 404, first external leads 406, conductive pads 408 connected to the first inner leads 404, second inner leads 410, and second external leads 412. At 304, a heat sink 414 is attached to the leadframe 402 resulting in the configuration of FIG. 4B. The heat sink 414 includes conductive pads 416 and a die attach pad 418. A gap, not shown, separates the conductive pads 416 and extends into the die attach pad 418. A closed end of the gap terminates in the die attach pad 418 and includes a beveled inner wall 420 as described herein.

At 306, an insulating tape 422 is placed on a first surface 424 of the die attach pad 418 resulting in the configuration of FIG. 4C. At 308, a die 426 is placed on the insulating tape 422 resulting in the configuration of FIG. 4D. The insulating tape 422 isolates the die 426 from the die attach pad 418 of the heat sink 414. At 310, wire bonds 428 are attached from the die 426 to the second inner leads 410 resulting in the configuration of FIG. 4E. At 312, a mold compound 430 is formed over the heat sink 414, the die 426, the wire bonds 428, and the first and second inner leads 404, 410 resulting in the configuration of FIG. 4F.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe, the leadframe including a first set of leads, a second set of leads, and conductive pads;
a heat sink attached to the conductive pads, the heat sink having an airgap prevention feature;
a die attached to the heat sink;
wire bonds connecting the die to the leadframe; and
a mold compound encapsulating the heat sink, the die, and the wire bonds.

2. The electronic device of claim 1, wherein the heat sink includes a pair of heat sink pads separated by a gap, and a die attach pad, the die attach pad having a semi-circular shape and connecting to an end of each of the pair of heat sink pads to form a U-shape.

3. The electronic device of claim 2, wherein the gap includes an open end and a closed end that terminates in the die attach pad, the closed end having a semi-circular shape with a beveled inner wall, the beveled inner wall preventing airgaps from forming upon formation of the mold compound.

4. The electronic device of claim 3, wherein the beveled inner wall extends from a first surface of the die attach pad to a second surface of the die attach pad at an angle in a range of approximately 95° to 145° with respect to the first surface.

5. The electronic device of claim 2, wherein the die is attached to the die attach pad.

6. The electronic device of claim 5 further comprising an insulating tape disposed between the die and the die attach pad of the heat sink.

7. The electronic device of claim 1, wherein the first set of leads includes first inner leads and first external leads, wherein the second set of leads includes second inner leads and second external leads.

8. The electronic device of claim 7, wherein the first inner leads are connected to the conductive pads and the second inner leads are connected to the die with the wire bonds.

9. The electronic device of claim 7, wherein the first inner leads and the second inner leads are encapsulated by the mold compound, and the first external leads and the second external leads are external to the mold compound.

10. The electronic device of claim 1, wherein the die is a current sensor.

11. A current sensor comprising:
a leadframe, the leadframe including a first set of leads, a second set of leads, and conductive pads;
a heat sink attached to the conductive pads, the heat sink including a pair of heat sink pads separated by a gap, and a die attach pad, the die attach pad having a semi-circular shape and connecting to an end of each of the pair of heat sink pads to form a U-shape, the die attach pad having an airgap prevention feature;
a die attached to the heat sink;
wire bonds connecting the die to the leadframe; and
a mold compound encapsulating the heat sink, the die, and the wire bonds.

12. The current sensor of claim 11, wherein the gap includes an open end and a closed end that terminates in the die attach pad, the closed end having a semi-circular shape with a beveled inner wall, the beveled inner wall preventing airgaps from forming upon formation of the mold compound.

13. The current sensor of claim 12, wherein the beveled inner wall extends from a first surface of the die attach pad to a second surface of the die attach pad at an angle in a range of approximately 95° to 145° with respect to the first surface.

14. The current sensor of claim 12, wherein the die is attached to the die attach pad.

15. The current sensor of claim 14 further comprising an insulating tape disposed between the die and the die attach pad of the heat sink.

16. The current sensor of claim 11, wherein the first set of leads includes first inner leads and first external leads, wherein the second set of leads includes second inner leads and second external leads.

17. The current sensor of claim 16, wherein the first inner leads are connected to the conductive pads and the second inner leads are connected to the die with the wire bonds.

18. The current sensor of claim 16, wherein the first inner leads and the second inner leads are encapsulated by the mold compound, and the first external leads and the second external leads are external to the mold compound.

19. A method comprising:
attaching a heat sink to a leadframe, the heat sink including conductive pads and a die attach pad, the die attach pad having a semi-circular gap formed therein having a beveled inner wall that extends from a first surface of the die attach pad to a second surface of the die attach pad;
attaching a die to the die attach pad;
attaching wire bonds from the die to the leadframe; and
forming a mold compound over the heat sink, the die, and the wire bonds.

20. The method of claim 19, wherein prior to attaching a die to the die attach pad, the method includes attaching insulating tape on the die attach pad.
